(19) United States
(12) Patent Application Publication
(10) Pub. No.: US 2017/0369653 A1
(43) Pub. Date: Dec. 28, 2017

(54) POLYAMIC ACID, POLYIMIDE, POLYIMIDE FILM AND COPPER CLAD LAMINATE USING THE SAME

(71) Applicant: Zhen Ding Technology Co., Ltd., Tayuan (TW)

(72) Inventors: YU-WEN KAO, Taoyuan (TW); MAO-FENG HSU, Taoyuan (TW); SHOU-JUI HSIANG, Taoyuan (TW); SZU-HSIANG SU, Taoyuan (TW); CHIA-YIN TENG, Taoyuan (TW)

(21) Appl. No.: 15/497,322

(22) Filed: Apr. 26, 2017

(30) Foreign Application Priority Data
Jun. 23, 2016 (TW) 105119803

(51) Int. Cl. C08G 73/10; C08J 5/18; H05K 3/10; H05K 1/09; H05K 1/03

(52) U.S. Cl. CPC C08G 73/1085; H05K 1/09; H05K 1/0353; H05K 3/10; C08J 5/18; C08J 2379/08; H05K 2201/0154

(57) ABSTRACT

A polyamic acid as a polymer of a dianhydride monomer and a diamine monomer is disclosed. The dianhydride monomer is an aromatic tetrabasic carboxylic acid dianhydride monomer. The diamine monomer comprises a diamine monomer containing pyrimidinyl and an aromatic diamine monomer. A polyimide, a polyimide film and a copper clad laminate using the polyamic acid are also provided.

### FIELD

The subject matter herein generally relates to a polyamic acid, a polyimide using the polyamic acid, a polyimide film using the polyimide, and a copper clad laminate using the polyimide film.

### BACKGROUND

Printed circuit board (PCB) is usually made by at least one copper clad laminate and at least one electronic component. A copper clad laminate includes a polyimide film and at least one copper foil attached to the surface of the polyimide film. The polyimide film is formed by coating a polyamic acid to the surface of the copper foil. During the process of making the printed circuit board, a portion of the copper foil will be moved away from a region of the polyimide film, to have the region of the polyimide film exposed. The exposed region of the polyimide film needs to be created accurately, to allow a CCD camera to accurately position the electronic component. The higher transparency of the exposed region, the better accurately positioning of the electronic component. In the copper clad laminate, the lower surface roughness of the copper foil, the higher transparency of the exposed region of the polyimide film. Conversely, the lower surface roughness of the copper foil, the weaker combined strength between the copper foil and the polyimide film.

### BRIEF DESCRIPTION OF THE DRAWINGS

Implementations of the present technology will now be described, by way of example only, with reference to the attached figures.

FIG. 1 is a flowchart of a method for making the polyamic acid in accordance with an exemplary embodiment

FIG. 2 is a diagrammatic view of an exemplary embodiment of a copper clad laminate.

FIG. 3 is a flowchart of a method for making a copper clad laminate in accordance with an exemplary embodiment.

FIG. 4 is a diagrammatic view of an exemplary embodiment of a polyimide film formed on a substrate.

FIG. 5 is a diagrammatic view of a printed circuit board according to an exemplary embodiment of the present application.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

Several definitions that apply throughout this disclosure will now be presented.

The term “comprising” when utilized, means “including, but not necessarily limited to”; it specifically indicates open-ended inclusion or membership in the so-described combination, group, series, and the like. The term “about” when utilized, means “not only include the numerical value, but also include numbers close to the stated numerical value”.

In an exemplary embodiment, a polyamic acid is a condensation reaction product of a dianhydride monomer and a diamine monomer. The dianhydride monomer is an aromatic tetrabasic carboxylic acid dianhydride monomer. The diamine monomer comprises a diamine monomer containing pyrimidinyl and an aromatic diamine monomer.

The polyamic acid has at least one pyrimidinyl.

The polyamic acid comprises a solid component and a liquid component. The solid component has a mass percentage of about 15% to about 30% of the total mass of the polyamic acid.

The polyamic acid has a viscosity of about 25000 CPS to about 80000 CPS.

The diamine monomer containing pyrimidinyl has a molar weight percentage of about 3% to about 8% of the total molar weight of the diamine monomer, insuring that a polyimide film made by the polyamic acid has a high adhesion strength and a high transparency. Experiment shows that, when the diamine monomer containing pyrimidinyl has a molar weight percentage more than 8% of the total molar weight of the diamine monomer, an increasing rate of the adhesion strength of the polyimide film decrease, while the transparency of the polyimide film is decreased because of a high charge transfer effect during the process of the diamine monomer containing pyrimidinyl absorbing light.

The aromatic diamine monomer has a molar weight percentage of about 92% to about 97% of the total molar weight of the diamine monomer.

The molar ratio of the dianhydride monomer and the diamine monomer is about 0.9:1 to about 1.1:1.

The aromatic tetrabasic carboxylic acid dianhydride monomer may be selected from a group consisting of Benzene-1,2,4,5-tetracarboxylic dianhydride (PMDA), 3,3′,4,4′-Biphenyltetracarboxylic dianhydride (BPDA), 4,4′-Oxydiphthalic anhydride (ODPA), 3,4′-Oxydiphthalic Anhydride (A-ODPA), Benzophenone-3,3′,4,4′-tetracarboxylic dianhydride (BTDA), 3,3′,4,4′-Diphenylsulfonetetracarboxylic Dianhydride (DSDA), 4,4′-(Hexafluoroisopropylidene)diphthalic anhydride (6FDA), or any combination thereof.

The diamine monomer containing pyrimidinyl may be selected from a group consisting of 1,2,4-Triazole-3,5-diamine (DZT), 2-(4-Aminophenyl)-1H-benzimidazol-5-amine (APBIA), 4,4′-pyrimidine-2,5-diyldianiline (PRM), or any combination thereof

A chemical structure formula of the DTZ is:

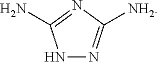

A chemical structure formula of the APBIA is:

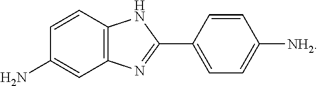 [SMILES: Nc1ccc(-c2nc3cc(N)ccc3[nH]2)cc1]

A chemical structure formula of the PRM is:

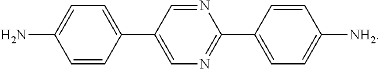 [SMILES: Nc1ccc(-c2cnc(-c3ccc(N)cc3)nc2)cc1]

The aromatic diamine monomer may be selected from a group consisting of 4,4′-Oxydianiline (ODA), p-Phenylenediamine (PDA), m-Phenylenediamine (m-PDA), 4,4′-Bis(4-aminophenoxy)biphenyl (BAPB), 1,4-Benzenedicarboxylic acid bis(4-aminophenyl) ester (BAPT), 4,4′-(4,4′-Isopropylidenediphenyl-1,1′-diyldioxy)dianiline (m-BAPP), 4,4′-(1,3-Phenylenedioxy)dianiline (TPE-R), 9,9-Bis(4-amino-3-fluorophenyl)fluorene (BFAF), 2,2′-Bis(trifluoromethyl)benzidine (22TFMB), 1,3-Bis(3-aminophenoxy)benzene (TPE-M), or any combination thereof.

In an exemplary embodiment, a polyimide is formed by the polyamic acid. The polyimide is an imidization product of the polyamic acid. The polyimide is formed by putting the polyamic acid in a high temperature, to have the polyamic acid cyclized, in other words, to have the polyamic acid dehydrate and close loops. The high temperature is about 300 degrees Celsius to about 400 degrees Celsius.

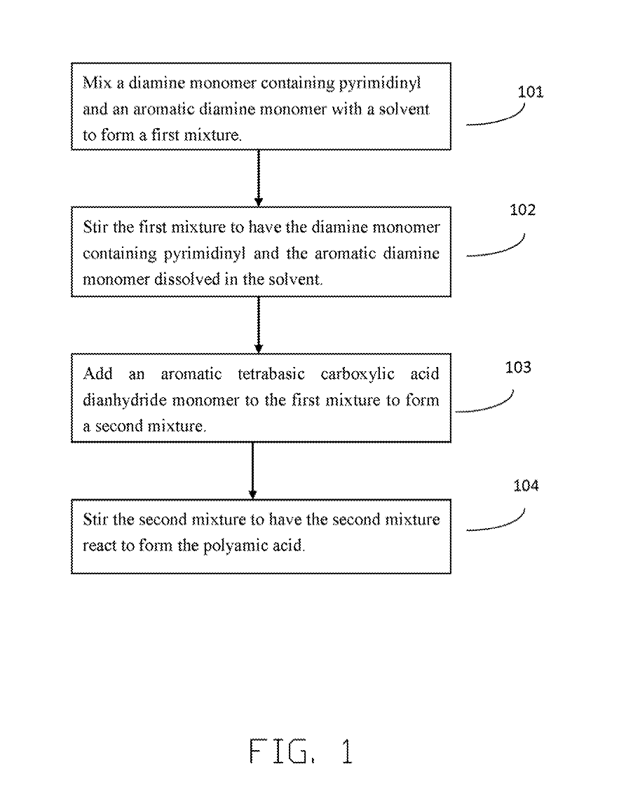

FIG. 1 illustrates a flowchart of a method for making the polyamic acid in accordance with an exemplary embodiment. The exemplary method is provided by way of example, as there are a variety of ways to carry out the method. Each block shown in the figure represents one or more processes, methods, or subroutines, carried out in the exemplary method. Furthermore, the illustrated order of blocks is by example only and the order of the blocks can change. Additional blocks may be added or fewer blocks may be utilized, without departing from this disclosure. The exemplary method may begin at block 101.

At block 101, a diamine monomer containing pyrimidinyl and an aromatic diamine monomer are mixed with a solvent to form a first mixture.

At block 102, the first mixture is stirred to have the diamine monomer containing pyrimidinyl and the aromatic diamine monomer dissolved in the solvent. In at least one exemplary embodiment, the stirring speed is 1400 rpm.

At block 103, an aromatic tetrabasic carboxylic acid dianhydride monomer is added to the first mixture to form a second mixture.

At block 104, the second mixture is stirred for a period of time, to have the second mixture react to form the polyamic acid.

The solvent is a bipolar aprotic solvent. In at least one exemplary embodiment, the bipolar aprotic solvent may be selected from a group consisting of bimethyl formamide (DMF), dimethyl acetamide (DMAC), N-Methylpyrrolidone (NMP), dimethyl sulfoxide (DMSO), or any combination thereof. The amount of the solvent may be adjusted, ensuring that all the above components may be dissolved in the solvent.

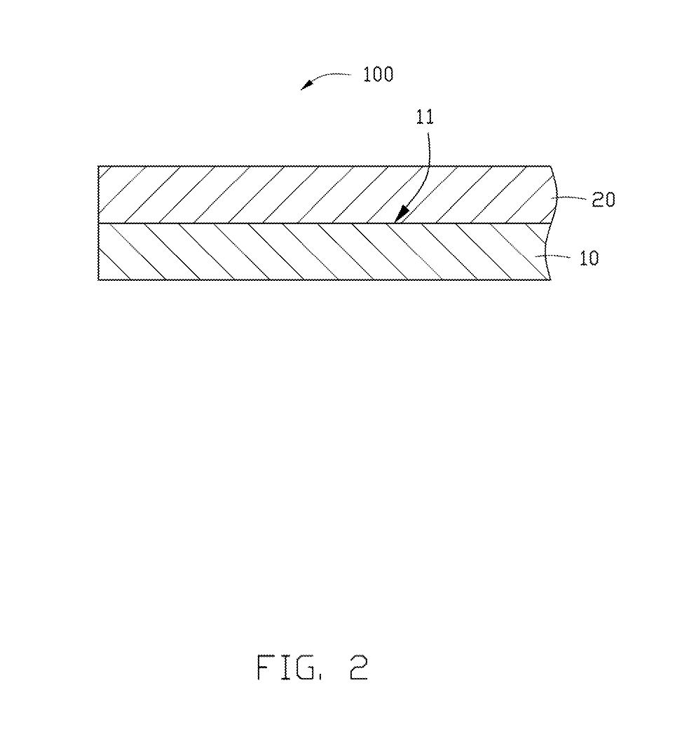

FIG. 2 illustrates an exemplary embodiment of a copper clad laminate 100 includes a copper foil 10 and a polyimide film 20. The copper foil 10 includes a connecting surface 11. The polyimide film 20 is attached on the connecting surface 11.

In at least one exemplary embodiment, the surface roughness of the connecting surface 11 is less than 0.5 μm.

The polyimide film 20 is formed by coating the polyamic acid on the connecting surface 11 of the copper foil 10, and then cyclizing at a high temperature of about 300 degrees Celsius to about 400 degrees Celsius. As the polyamic acid includes pyrimidinyl, and the pyrimidinyl can coordinate with copper ions in the connecting surface of the copper foil 10, thereby the polyamic acid has strong binding force with the copper foil 10. The polyimide film 20 thereby formed by the polyamic acid has a strong binding force with the copper foil 10. The connecting surface 11 of the copper foil 10 has a low surface roughness, thereby the surface of the polyimide film 20 formed on the connecting surface 11 is smooth, thereby the polyimide film 20 has a high transparency.

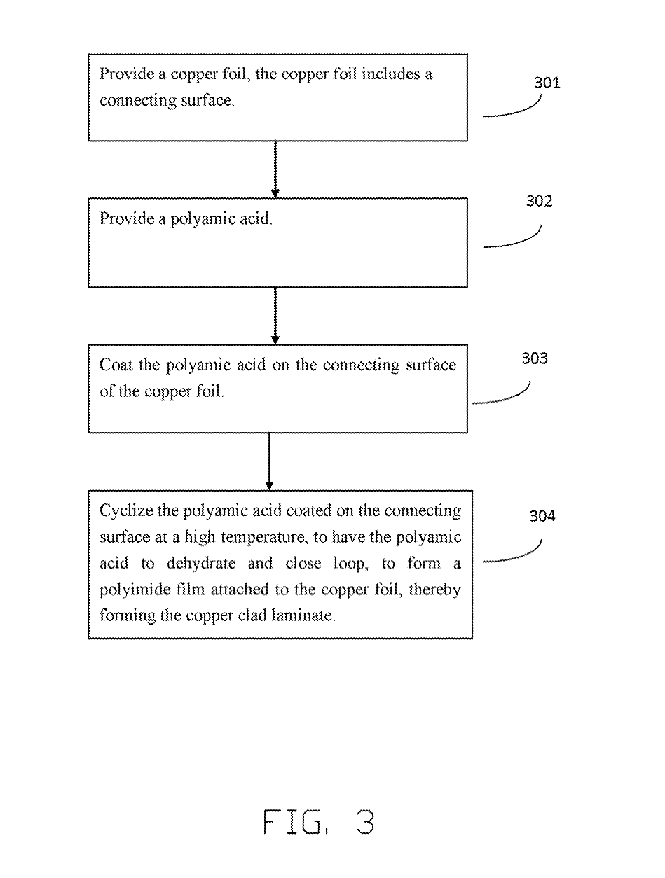

FIG. 3 illustrates a flowchart of a method for making the copper clad laminate 100 in accordance with an exemplary embodiment. The exemplary method is provided by way of example, as there are a variety of ways to carry out the method. Each block shown in the figure represents one or more processes, methods, or subroutines, carried out in the exemplary method. Furthermore, the illustrated order of blocks is by example only and the order of the blocks can change. Additional blocks may be added or fewer blocks may be utilized, without departing from this disclosure. The exemplary method may begin at block 301.

At block 301, a copper foil 10 is provided. The copper foil 10 includes a connecting surface 11, the surface roughness of the connecting surface 11 is less than 0.5 μm.

At block 302, a polyamic acid is provided.

The polyamic acid is a condensation reaction product of a dianhydride monomer and a diamine monomer. The dianhydride monomer is an aromatic tetrabasic carboxylic acid dianhydride monomer. The diamine monomer comprises a diamine monomer containing pyrimidinyl and an aromatic diamine monomer.

At block 303, the polyamic acid is coated on the connecting surface 11 of the copper foil 10.

At block 304, the polyamic acid coated on the connecting surface 11 is cyclized at a high temperature of about 300 degrees Celsius to about 400 degrees Celsius, to have the polyamic acid dehydrate and close loops, thereby forming a polyimide film 20 on the connecting surface of the copper foil 10, thereby forming the copper clad laminate 100.

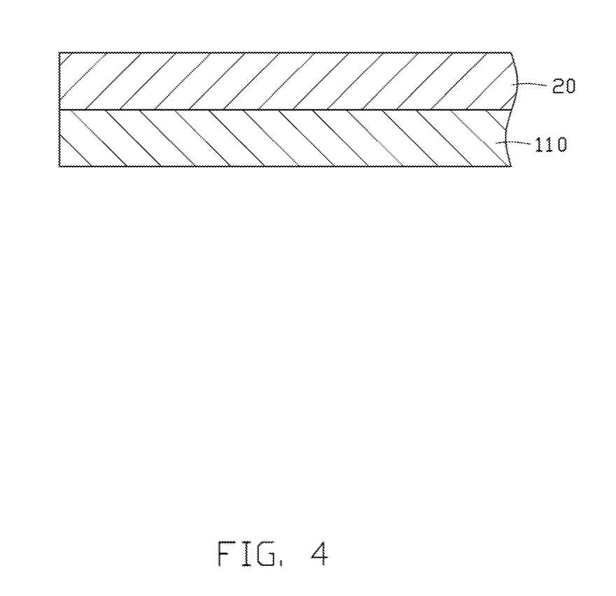

FIG. 4 illustrates a polyimide film 20 formed on a substrate 110. The polyimide film 20 is formed by coating the polyamic acid on a surface of the substrate 110, and then cyclized at a high temperature of about 300 degrees Celsius to about 400 degrees Celsius, to have the polyamic acid dehydrate and close loops. In other words, the polyimide film 20 comprises the polymide.

The substrate 110 maybe a release film, a metal foil, or a resin film.

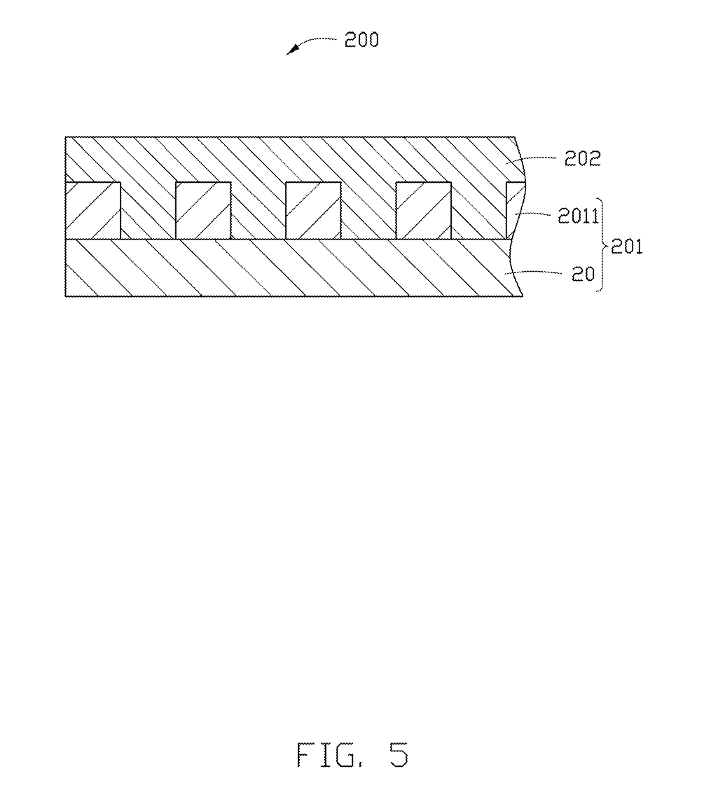

FIG. 5 illustrates an exemplary embodiment of a printed circuit board 200 including a circuit substrate 201, a covering film 202 attached to at least one surface of the circuit substrate 201, and at least one electronic component (not shown).

The circuit substrate 201 includes a polyimide film 20, and a conductive circuit layer 2011 attached to at least one surface of the polyimide film 20. The conductive circuit layer 2011 is formed by etching the copper foil 10 of the copper clad laminate 100. The covering film 202 is attached to the surface of the conductive circuit layer 2011 away from the polyimide film 20.

### EXAMPLE 1

NMP, PDA, ODA, and DZT were added into a 500 mL container to form a first mixture, the mixture was stirred to have the PDA, ODA, and DZT dissolved in the NMP. BPDA was added in to the container to form a second mixture, the second mixture was stirred for 12 hours to form a polyamic acid.

The mass of the NMP is 167.0 g, the mass of the PDA is 6.13 g, the mass of the ODA is 4.33 g, the mass of the DZT is 0.08 g, the mass of the BPDA is 23.18 g.

### EXAMPLE 2

NMP, PDA, ODA, and DZT were added into a 500 mL container to form a first mixture, the mixture was stirred to have the PDA, ODA, and DZT dissolved in the NMP. BPDA was added in to the container to form a second mixture, the second mixture was stirred for 12 hours to form a polyamic acid.

The mass of the NMP is 166.9 g, the mass of the PDA is 5.96 g, the mass of the ODA is 4.33 g, the mass of the DZT is 0.24 g, the mass of the BPDA is 23.18 g.

### EXAMPLE 3

NMP, PDA, ODA, and DZT were added into a 500 mL container to form a first mixture, the mixture was stirred to have the PDA, ODA, and DZT dissolved in the NMP. BPDA was added in to the container to form a second mixture, the second mixture was stirred for 12 hours to form a polyamic acid.

The mass of the NMP is 166.7 g, the mass of the PDA is 5.53 g, the mass of the ODA is 4.33 g, the mass of the DZT is 0.63 g, the mass of the BPDA is 23.18 g.

### EXAMPLE 4

NMP, PDA, ODA, and DZT were added into a 500 mL container to form a first mixture, the mixture was stirred to have the PDA, ODA, and DZT dissolved in the NMP. BPDA was added in to the container to form a second mixture, the second mixture was stirred for 12 hours to form a polyamic acid.

The mass of the NMP is 166.7 g, the mass of the PDA is 5.36 g, the mass of the ODA is 4.33 g, the mass of the DZT is 0.78 g, the mass of the BPDA is 23.18 g.

### COMPARATIVE EXAMPLE 1

NMP, PDA, and ODA were added into a 500 mL container to form a first mixture, the mixture was stirred to have the PDA, ODA, and DZT dissolved in the NMP. BPDA was added in to the container to form a second mixture, the second mixture was stirred for 12 hours to form a polyamic acid.

The mass of the NMP is 167.0 g, the mass of the PDA is 6.21 g, the mass of the ODA is 4.33 g, the mass of the BPDA is 23.18 g.

In the examples 1˜4 and comparative example 1, the molecular weight of the PDA is 108 g/mol, the molecular weight of the ODA is 200.24 g/mol, the molecular weight of the DZT is 99.1 g/mol, and the molecular weight of the BPDA is 294.2 g/mol.

Copper clad laminates 100 were formed by the polyamic acid of the above examples 1˜4 and comparative example 1. The copper foil 10 used in the copper clad laminates 100 was GHYS-82F-HA-V2, the surface roughness of the copper foil 10 was 0.45 μm.

The copper clad laminates were subjected to a peel strength test, a thermal resistance test, and a solder float resistance test. The test results are shown in table 1.

The solder float resistance test was carried out by forming solder masks on the surface of the polyimide film, then exposing the copper clad laminates to a temperature equal to or greater than 288 degrees Celsius for 10 seconds, and observing whether the solder masks were peeled off or dropped from the copper clad laminates.

The thermal resistance test was carried out by heating the copper clad laminates, and observing the temperature at which the copper clad laminates deformed.

A portion of copper foil 10 attached to a region of the polyimide film 20 was etched, thereby the region of the polyimide film 20 was exposed, and a transmittance test was carried out on the exposed region of the polyimide film 20. The test results are shown in table 1.

TABLE 1

| | product | | | | |
|---|---|---|---|---|---|
| | | | | | comparative |
| property | example 1 | example 2 | example 3 | example 4 | example 1 |
| peel strength | 0.59 kgf/cm | 0.76 kgf/cm | 0.90 kgf/cm | 0.91 kgf/cm | 0.56 kgf/cm |
| thermal | 312 degrees | 315 degrees | 330 degrees | 335 degrees | 309 degrees |
| resistance | Celsius | Celsius | Celsius | Celsius | Celsius |
| solder float | 288 degrees | 288 degrees | 288 degrees | 288 degrees | 288 degrees |
| resistance | Celsius for | Celsius for 10 | Celsius for 10 | Celsius for 10 | Celsius for 10 |
| | 10 seconds | seconds | seconds | seconds | seconds |
| | not peeled off | not peeled off | not peeled off | not peeled off | not peeled off |
| transparency | 69% | 68% | 60% | 53% | 70% |

Table 1 illustrates that the copper clad laminates formed by the polyamic acid of the above examples 1˜4 have improved peel strength, improved thermal resistance, good solder float resistance, and high transparency.

The embodiments shown and described above are only examples. Even though numerous characteristics and advantages of the present technology have been set forth in the foregoing description, together with details of the structures and function of the present disclosure, the disclosure is illustrative only, and changes can be made in the detail, including in matters of shape, size, and arrangement of the parts within the principles of the present disclosure, up to and including, the full extent established by the broad general meaning of the terms used in the claims.

What is claimed is:

1. A polyamic acid comprising:
a condensation reaction product of:
a dianhydride monomer; and
a diamine monomer;
wherein the dianhydride monomer is an aromatic tetrabasic carboxylic acid dianhydride monomer, the diamine monomer comprises a diamine monomer containing pyrimidinyl and an aromatic diamine monomer.

2. The polyamic acid of claim 1, wherein a molar ratio of the dianhydride monomer and the diamine monomer is about 0.9:1 to about 1.1:1.

3. The polyamic acid of claim 1, wherein the diamine monomer containing pyrimidinyl has a molar weight percentage of about 3% to about 8% of the total molar weight of the diamine monomer, the aromatic diamine monomer has a molar weight percentage of about 92% to about 97% of the total molar weight of the diamine monomer.

4. The polyamic acid of claim 1, wherein the aromatic tetrabasic carboxylic acid dianhydride monomer is selected from a group consisting of Benzene-1,2,4,5-tetracarboxylic dianhydride, 3,3′,4,4′-Biphenyltetracarboxylic dianhydride, 4,4′-Oxydiphthalic anhydride, 3,4′-Oxydiphthalic Anhydride, Benzophenone-3,3′,4,4′-tetracarboxylic dianhydride, 3,3′,4,4′-Diphenylsulfonetetracarboxylic Dianhydride, 4,4′-(Hexafluoroisopropylidene)diphthalic anhydride, or any combination thereof.

5. The polyamic acid of claim 1, wherein the diamine monomer containing pyrimidinyl is selected from a group consisting of 1,2,4-Triazole-3,5-diamine, 2-(4-Aminophenyl)-1H-benzimidazol-5-amine, 4,4′-pyrimidine-2,5-diyldianiline, or any combination thereof.

6. The polyamic acid of claim 1, wherein the aromatic diamine monomer is selected from a group consisting of 4,4′-Oxydianiline, p-Phenylenediamine, m-Phenylenediamine, 4,4′-Bis(4-aminophenoxy)biphenyl, 1,4-Benzenedicarboxylic acid bis(4-aminophenyl) ester, 4,4′-(4,4′-Isopropylidenediphenyl-1,1′-diyldioxy)dianiline, 4,4′-(1,3-Phenylenedioxy)dianiline, 9,9-Bis(4-amino-3-fluorophenyl)fluorene, 2,2′-Bis(trifluoromethyl)benzidine, 1,3-Bis(3-aminophenoxy)benzene, or any combination thereof.

7. A polyimide is an imidization product of:
a polyamic acid, the polyamic acid comprises a condensation reaction product of:
a dianhydride monomer; and
a diamine monomer;
wherein the dianhydride monomer is an aromatic tetrabasic carboxylic acid dianhydride monomer, the diamine monomer comprises a diamine monomer containing pyrimidinyl and an aromatic diamine monomer.

8. The polyimide of claim 7, wherein a molar ratio of the dianhydride monomer and the diamine monomer is about 0.9:1 to about 1.1:1.

9. The polyimide of claim 7, wherein the diamine monomer containing pyrimidinyl has a molar weight percentage of about 3% to about 8% of the total molar weight of the diamine monomer, the aromatic diamine monomer has a molar weight percentage of about 92% to about 97% of the total molar weight of the diamine monomer.

10. The polyimide of claim 7, wherein the aromatic tetrabasic carboxylic acid dianhydride monomer is selected from a group consisting of Benzene-1,2,4,5-tetracarboxylic dianhydride, 3,3′,4,4′-Biphenyltetracarboxylic dianhydride, 4,4′-Oxydiphthalic anhydride, 3,4′-Oxydiphthalic Anhydride, Benzophenone-3,3′,4,4′-tetracarboxylic dianhydride, 3,3′,4,4′-Diphenyl sulfonetetracarboxylic Dianhydride, 4,4′-(Hexafluoroisopropylidene)diphthalic anhydride, or any combination thereof.

11. The polyimide of claim 7, wherein the diamine monomer containing pyrimidinyl is selected from a group consisting of 1,2,4-Triazole-3,5-diamine, 2-(4-Aminophenyl)-1H-benzimidazol-5-amine, 4,4′-pyrimidine-2,5-diyldianiline, or any combination thereof.

12. The polyimide of claim 7, wherein the aromatic diamine monomer is selected from a group consisting of 4,4′-Oxydianiline, p-Phenylenediamine, m-Phenylenediamine, 4,4′-Bis(4-aminophenoxy)biphenyl, 1,4-Benzenedicarboxylic acid bis(4-aminophenyl) ester, 4,4′-(4,4′-Isopropylidenediphenyl-1,1′-diyldioxy)dianiline, 4,4′-(1,3-Phenylenedioxy)dianiline, 9,9-Bis(4-amino-3-fluorophenyl)fluorene, 2,2′-Bis(trifluoromethyl)benzidine, 1,3-Bis(3-aminophenoxy)benzene, or any combination thereof.

13. A polyimide film comprising:
a polyimide, the polyimide is an imidization product of:
a polyamic acid, the polyamic acid comprises a condensation reaction product of:
a dianhydride monomer; and
a diamine monomer;
wherein the dianhydride monomer is an aromatic tetrabasic carboxylic acid dianhydride monomer, the diamine monomer comprises a diamine monomer containing pyrimidinyl and an aromatic diamine monomer.

14. The polyimide film of claim 13, wherein a molar ratio of the dianhydride monomer and the diamine monomer is about 0.9:1 to about 1.1:1.

15. The polyimide film of claim 13, wherein the diamine monomer containing pyrimidinyl has a molar weight percentage of about 3% to about 8% of the total molar weight of the diamine monomer, the aromatic diamine monomer has a molar weight percentage of about 92% to about 97% of the total molar weight of the diamine monomer.

16. The polyimide film of claim 13, wherein the aromatic tetrabasic carboxylic acid dianhydride monomer is selected from a group consisting of Benzene-1,2,4,5-tetracarboxylic dianhydride, 3,3′,4,4′-Biphenyltetracarboxylic dianhydride, 4,4′-Oxydiphthalic anhydride, 3,4′-Oxydiphthalic Anhydride, Benzophenone-3,3′,4,4′-tetracarboxylic dianhydride, 3,3′,4,4′-Diphenylsulfonetetracarboxylic Dianhydride, 4,4′-(Hexafluoroisopropylidene)diphthalic anhydride, or any combination thereof.

17. The polyimide film of claim 13, wherein the diamine monomer containing pyrimidinyl is selected from a group consisting of 1,2,4-Triazole-3,5-diamine, 2-(4-Aminophenyl)-1H-benzimidazol-5-amine, 4,4′-pyrimidine-2,5-diyldianiline, or any combination thereof.

18. The polyimide film of claim 13, wherein the aromatic diamine monomer is selected from a group consisting of 4,4′-Oxydianiline, p-Phenylenediamine, m-Phenylenediamine, 4,4′-Bis(4-aminophenoxy)biphenyl, 1,4-Benzenedicarboxylic acid bis(4-aminophenyl) ester, 4,4′-(4,4′-isopropylidenediphenyl-1,1′-diyldioxy)dianiline, 4,4′-(1,3-Phenylenedioxy)dianiline, 9,9-Bis(4-amino-3-fluorophenyl)fluorene, 2,2′-Bis(trifluoromethyl)benzidine, 1,3-Bis(3-aminophenoxy)benzene, or any combination thereof.

19. A copper clad laminate comprising:
a copper foil, the copper foil comprises a connecting surface; and
a polyimide film attached to the connecting surface of the copper foil, the polyimide film comprising:
a polyimide, the polyimide is an imidization product of:
a polyamic acid, the polyamic acid comprises a condensation reaction product of:
a dianhydride monomer; and
a diamine monomer;
wherein the dianhydride monomer is an aromatic tetrabasic carboxylic acid dianhydride monomer, the diamine monomer comprises a diamine monomer containing pyrimidinyl and an aromatic diamine monomer.

20. The copper clad laminate of claim 19, wherein a molar ratio of the dianhydride monomer and the diamine monomer is about 0.9:1 to about 1.1:1.

21. The copper clad laminate of claim 19, wherein the diamine monomer containing pyrimidinyl has a molar weight percentage of about 3% to about 8% of the total molar weight of the diamine monomer, the aromatic diamine monomer has a molar weight percentage of about 92% to about 97% of the total molar weight of the diamine monomer.

22. The copper clad laminate of claim 19, wherein the aromatic tetrabasic carboxylic acid dianhydride monomer is selected from a group consisting of Benzene-1,2,4,5-tetracarboxylic dianhydride, 3,3′,4,4′-Biphenyltetracarboxylic dianhydride, 4,4′-Oxydiphthalic anhydride, 3,4′-Oxydiphthalic Anhydride, Benzophenone-3,3′,4,4′-tetracarboxylic dianhydride, 3,3′,4,4′-Diphenylsulfonetetracarboxylic Dianhydride, 4,4′-(Hexafluoroisopropylidene)diphthalic anhydride, or any combination thereof.

23. The copper clad laminate of claim 19, wherein the diamine monomer containing pyrimidinyl is selected from a group consisting of 1,2,4-Triazole-3,5-diamine, 2-(4-Aminophenyl)-1H-benzimidazol-5-amine, 4,4′-pyrimidine-2,5-diyldianiline, or any combination thereof.

24. The copper clad laminate of claim 19, wherein the aromatic diamine monomer is selected from a group consisting of 4,4′-Oxydianiline, p-Phenylenediamine, m-Phenylenediamine, 4,4′-Bis(4-aminophenoxy)biphenyl, 1,4-Benzenedicarboxylic acid bis(4-aminophenyl) ester, 4,4′-(4,4′-isopropylidenediphenyl-1,1′-diyldioxy)dianiline, 4,4′-(1,3-Phenylenedioxy)dianiline, 9,9-Bis(4-amino-3-fluorophenyl)fluorene, 2,2′-Bis(trifluoromethyl)benzidine, 1,3-Bis(3-aminophenoxy)benzene, or any combination thereof.
